(19) United States
(12) Patent Application Publication
(10) Pub. No.: US 2007/0193719 A1
(43) Pub. Date: Aug. 23, 2007

(54) COOLABLE CARRIER PLATE FOR TARGETS IN VACUUM ATOMIZATION SYSTEMS

(75) Inventors: Michael Huhn, Dresden (DE); Carsten Deus, Dresden (DE); Goetz Teschner, Dresden (DE); Erwin Zschieschang, Dresden (DE)

Correspondence Address: HESLIN ROTHENBERG FARLEY & MESITI PC, 5 COLUMBIA CIRCLE, ALBANY, NY, 12203, US

(73) Assignee: VON ARDENNE Anlagentechnik GmbH, Dresden (DE)

(21) Appl. No.: 11/676,708

(22) Filed: Feb. 20, 2007

(30) Foreign Application Priority Data
Feb. 23, 2006 (DE) 10 2006 008 973.1

(51) Int. Cl. F28F 3/14; H05K 7/20

(52) U.S. Cl. 165/80.4; 165/170; 361/699

(57) ABSTRACT

A coolable carrier plate for targets in vacuum atomization systems has a connection surface and at least one fastening support for connecting the carrier plate to a component provided for this purpose, at least one sealant for sealing the connection surface, at least one cavity for conveying a coolant with a coolant inlet and a coolant outlet, and a supporting surface for supporting a target. The cavity is formed by a coolant channel or network of coolant channels that runs inside the carrier plate.

### BACKGROUND ART

The invention relates to a coolable carrier plate for targets in vacuum atomization systems.

For coating substrates under high vacuum, expansive, even targets whose material is removed by means of cathode atomization and then separated out on the substrate are used amongst other things. The need to cool the target due to the energy input through the magnetic field formed behind the target is known from the state of the art.

To this end, the target is arranged on a coolable carrier plate. Normally, by means of an expansive recess, the carrier plate is almost trough-shaped, the recess being covered by the target and a cavity thus being formed behind the target, with a cooling liquid flowing through the cavity to cool the target. This arrangement is also called a membrane plate or sandwich plate.

One disadvantage of this solution is that the cooling liquid may only be guided through the cavity at a very low pressure, as otherwise the carrier plate together with the target applied to it is distorted due to the large differential pressure between the pressure prevailing on one side of the target, i.e. in the cavity, and the high vacuum prevailing on the other side of the target, i.e. inside the vacuum chamber. In extreme cases, such distortion can even lead to collapse of the sandwich plate.

The low wall thickness of the carrier plate required for optimum cooling of the target is contrary to its mechanical stability and sets narrow boundaries for the maximum possible size of the carrier plate. Furthermore, this solution has a water/vacuum seal that is positioned inside the vacuum chamber and has a negative impact on the process reliability of the coating system.

### SUMMARY OF THE INVENTION

Starting from this state of the art, the object of the present invention is to indicate a coolable carrier plate for targets in vacuum atomization systems that enables cooling of expansive targets, has high mechanical stability, enables process-reliable supply and drainage of the coolant and enables problem-free replacement of spent targets.

The coolable carrier plate for targets in vacuum atomization systems with a connection surface and at least one fastening support for connecting the carrier plate to a component provided for this purpose, at least one sealant for sealing the connection surface, at least one cavity for conveying a coolant with a coolant inlet and a coolant outlet, and a supporting surface for supporting a target, is characterized in that the cavity is formed through a coolant channel or a network of coolant channels that runs inside the carrier plate.

In contrast to the state of the art, the cavity through which the coolant is guided is not formed through a trough-shaped recess in the carrier plate, but through at least one cooling channel. In the context of this application, a cooling channel refers to any coolant line arranged inside the carrier plate, for example a tubular or tunnel-shaped coolant line, whose cross-section remains almost constant across significant sections.

Advantageously, several cavities formed by a coolant channel or network of coolant channels are provided.

Particularly with carrier plates for targets whose main dimensions of length and width differ greatly, individual partial surfaces of the target are cooled separately by means of this measure. The advantage of several coolant-guiding cavities is that the length of the individual coolant channels or networks of coolant channels is reduced compared with an individual coolant channel or an individual network of coolant channels. Consequently, the coolant absorbs a lower quantity of heat in each coolant channel or network of coolant channels so that the difference between the inlet temperature and the outlet temperature of each individual coolant channel or network of coolant channels is reduced, thus increasing the cooling capacity of the carrier plate overall.

Preferably, the number of cavities formed through a coolant channel or network of coolant channels corresponds to the rounded ratio of length and width of the supporting surface.

As a result of this, for example at a ratio of 3:1 between the length and width of the supporting surface that largely reflects the corresponding ratio of the target to be supported, three coolant channels or networks of coolant channels are provided. This means that each partial surface of the supporting surface or surface of the target cooled by a coolant channel or network of coolant channels is almost square. The width of the supporting surface or target must be passed over by each coolant channel or network of coolant channels in any case. With the partial surface that is passed over by a coolant channel or network of coolant channels being restricted to a section of the length of the supporting surface that almost corresponds to the width of the supporting surface, a high cooling capacity is attained combined with a low number of coolant channels or networks of coolant channels.

In an advantageous embodiment, each coolant channel is structured in a meandering manner.

The meandering guiding of the coolant channel inside the carrier plate results in a larger, more expansive area of the supporting surface being coolable with an individual coolant channel that is intrinsically only suitable for cooling an almost lamellar surface section.

In another advantageous embodiment, each network of coolant channels has on the inlet and outlet side a collection channel through which the coolant is led from the coolant inlet into the coolant channels or from the coolant channels to the coolant outlet.

A particularly simple and therefore cost-effective design of a network of coolant channels is realized in this way, as the coolant channels and the collection channels can have a linear, easily produced shape. The coolant flowing through the coolant inlet is initially distributed in the first collection canal. Several coolant channels branch off from this collection channel, and the coolant flows into them. At the end of the coolant channels, the coolant flows into a second collection channel, into which the coolant canals feed. From this collection channel, the coolant flows to the coolant outlet and thus leaves the carrier plate.

It has also proved advantageous to arrange the sealant in such a way that all coolant inlets and coolant outlets are separated from all fastening supports.

Coolant emerging from a coolant circuit that has become leaky is thus prevented from penetrating the vacuum chamber through a fastening support.

An embodiment of the invention in which all fastening supports are arranged on the vacuum side and all coolant inlets and coolant outlets are arranged on the atmosphere side is particularly advantageous.

The fastenings for fastening the carrier plate to a component provided for this purpose are generally applied from the supporting surface, i.e. the fastening supports are situated on this side of the carrier plate inside the vacuum chamber and thus in a high vacuum. To prevent ambient air that penetrates through the fastening supports from destroying the high vacuum, it has proved useful to arrange the sealant in such a way that all fastening supports are arranged on the vacuum side. In the same way, the atmosphere-side arrangement of all coolant inlets and coolant outlets prevents coolant from entering the inside of the vacuum chamber if the coolant circuit ever becomes leaky.

In a further advantageous embodiment, each coolant inlet and each coolant outlet has an additional sealant.

By means of this measure, the safety of the carrier plate according to the invention against unwanted leakage of coolant and against penetration thereof into the vacuum chamber is again increased.

### BRIEF SUMMARY OF THE DRAWING FIGURES

The invention is described in further detail below on the basis of drawings.

FIG. 1 shows a view of the carrier plate according to the invention from the connection surface

FIG. 2 shows a cross-section of the carrier plate attached to a component provided for this purpose

FIG. 3 shows an embodiment of the carrier plate according to the invention with two cavities each formed through a meandering coolant channel

FIG. 4 shows an embodiment of the carrier plate according to the invention with two cavities each formed through a network of coolant channels.

### DETAILED DESCRIPTION

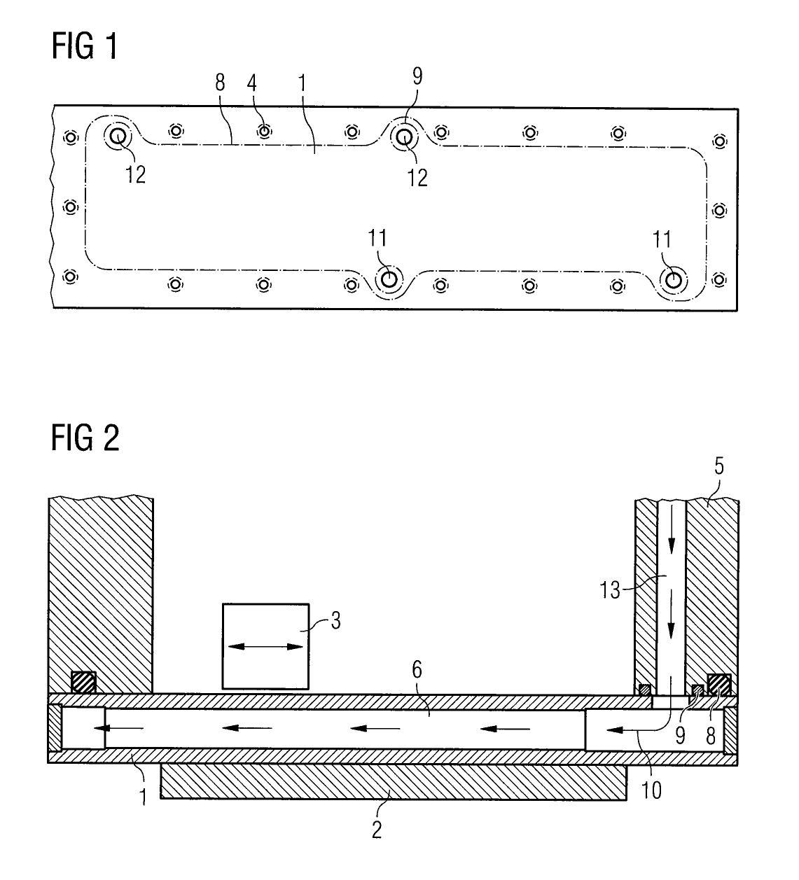

FIG. 1 shows a view of the carrier plate according to the invention from the connection surface.

Along the edges of the carrier plate 1, a plurality of fastening supports 4 is arranged, said means being designed as drilled holes in the execution example. Also in proximity to the edges, the carrier plate 1 has two coolant inlets 11 and two coolant outlets 12. The carrier plate 1 shown accordingly has two cavities (not shown) formed through coolant channels, for conveying a coolant. At each coolant inlet 11 and each coolant outlet 12, a local sealant 9 is provided in order to prevent leaks of the coolant circuits.

In addition, the carrier plate 1 shown has a circumferential sealant 8. The circumferential sealant 8 is arranged in such a way that all coolant inlets 11 and all coolant outlets 12 are separated from all fastening supports 4. All coolant inlets 11 and all coolant outlets 12 are arranged on the atmosphere side and all fastening supports 4 are arranged on the vacuum side.

FIG. 2 shows a cross-section of the carrier plate attached to a component provided for this purpose.

The external component 5 to which the carrier plate 1 is attached with fastenings (not shown) arranged in the fastening supports 4 (not shown) can, for example, be a magnetron housing or an adapter designed for this purpose. A moving magnetic field 3 is arranged behind the connection surface of the carrier plate 1, which connection surface is arranged on the atmosphere side, i.e. in a magnetron housing, for example. The connection surface is sealed in the area of the external component 5 by means of a circumferential sealant 8. A target 2 is arranged on the supporting surface of the carrier plate 1, which supporting surface is arranged on the vacuum side, i.e. inside the vacuum chamber.

The external component 5 has a guide channel 13 that feeds into the coolant inlet 11 of the carrier plate 1. A local sealant 9 for sealing the intersection between the guide channel 13 and the coolant inlet 11 is arranged between the guide channel 13 and the coolant inlet 11. In the same way, the external component 5 has a guide channel 13 (not shown) into which the coolant outlet 12 (not shown) of the carrier plate 1 feeds. Also between this guide channel 13 and the coolant outlet 12, a local sealant 9 for sealing the intersection between the coolant outlet 12 and the guide channel 13 is arranged.

The coolant flow 10 runs from the guide channel 13 through the coolant inlet 11 into the cavity of the carrier plate 1 formed through a coolant channel 6. The coolant channel 6 crosses through the inside of the carrier plate 1 in a meandering manner so that in the selected representation of the coolant outlet 12, the local sealant 9 arranged there as well as the guide channel 13 into which the coolant channel 6 feeds are no longer visible.

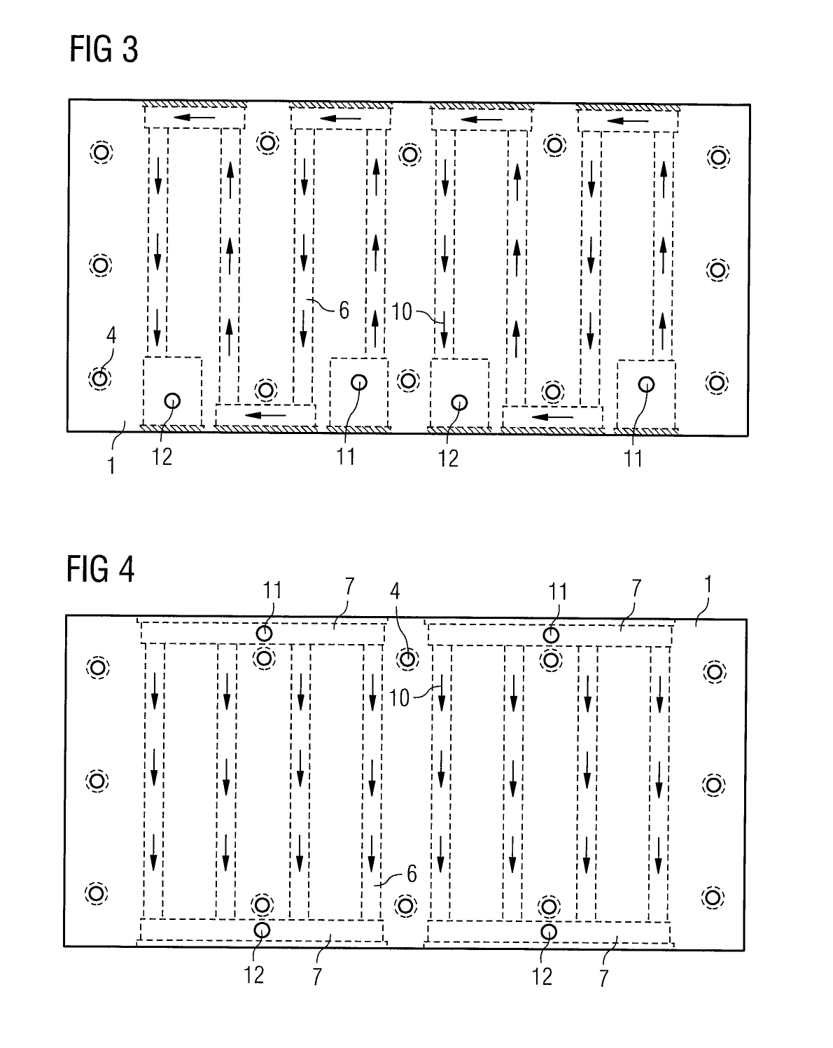

FIG. 3 shows an embodiment of the carrier plate according to the invention with two cavities each formed through a meandering coolant channel.

The rounded ratio of length and width of the carrier plate 1 is 2. Therefore, inside the carrier plate 1, two cavities each formed through a coolant channel are provided, through which cavities an almost square partial surface of the carrier plate 1 can be cooled. The edge area of the carrier plate 1 has a plurality of fastening supports 4 for fastening the carrier plate 1 to an external component 5 provided for this purpose.

Each cavity formed through a coolant channel 6 has a coolant inlet 11 and a coolant outlet 12.

The sections of the coolant channels 6 that run in the transverse direction of the carrier plate 1 are established by means of drilled holes, i.e. they have a circular cross-section. The sections of the coolant channels 6 that run in the longitudinal direction of the carrier plate 1 are established by means of milling, i.e. they have a rectangular cross-section. Compared with the trough-shaped recesses known from the state of the art, the cross-sections of the individual sections of the coolant channel 6 are almost the same size in the execution example, so that the flow rate and pressure of the coolant almost remain the same when the coolant flows through the cavity.

The individual sections of the coolant channel 6 are connected with each other in a meandering manner so that a surface section of the carrier plate 1 and not only a narrow strip can be cooled by means of the cooling channel 6. A coolant flow 10 flows through the cooling channel 6 from the coolant inlet 11 to the coolant outlet 12 and absorbs the heat that the target 2 (not shown) emits to the carrier plate 1.

FIG. 4 shows an embodiment of the carrier plate according to the invention with two cavities each formed through a network of coolant channels.

The rounded ratio of length and width of the carrier plate 1 is 2. Therefore, inside the carrier plate 1, two cavities each formed through a network of coolant channels 6 are provided, by means of which an almost square partial surface of the carrier plate 1 can be cooled. The edge area of the carrier plate 1 has a plurality of fastening supports 4 for fastening the carrier plate 1 to an external component 5 provided for this purpose.

Each cavity formed through a network of coolant channels 6 has a coolant inlet 11 and a coolant outlet 12.

The sections of the coolant channels 6 that run in the transverse direction of the carrier plate 1 are established by means of drilled holes, i.e. they have a circular cross-section. The sections of the collection channels 7 that connect the coolant channels 6 to a network and run in the longitudinal direction of the carrier plate 1 are established by means of milling, i.e. they have a rectangular cross-section. Compared with the trough-shaped recesses known from the state of the art, the cross-sections of the individual sections of the coolant channel 6 are almost the same size in the execution example, so that the flow rate and pressure of the coolant almost remain the same when the coolant flows through the cavity.

At their beginning and end, the individual coolant channels 6 are each connected with each other by means of a collection channel 7 so that a surface section of the carrier plate 1 and not only a narrow strip can be cooled by means of the network of the coolant channels 6. A coolant flow 10 flows from the coolant inlet 11 into a first collection channel 7. From there, the coolant flow 10 branches into the coolant channels 6, through which the coolant flow 10 then flows.

At their respective ends, the coolant channels 6 are connected by means of a second collection channel 7 into which the coolant flow flows after flowing through the coolant channels 6. From the second collection channel 7, the coolant flows to the coolant outlet 12 and then leaves the carrier plate 1. When flowing through the carrier plate 1, the coolant flow 10 absorbs the heat that the target 2 (not shown) emits to the carrier plate 1.

1. Coolable carrier plate for targets in vacuum atomization systems, the plate having a connection surface and at least one fastening support for connecting the carrier plate to an external component, at least one sealant for sealing the connection surface, at least one cavity for conveying a coolant with a coolant inlet and a coolant outlet, and a supporting surface for supporting a target, wherein the cavity is formed through a coolant channel or a network of coolant channels that runs inside the carrier plate.

2. Coolable carrier plate according to claim 1, wherein several cavities formed by a coolant channel or network of coolant channels are provided inside the carrier plate.

3. Coolable carrier plate according to claim 2, wherein the number of cavities formed by a coolant channel or network of coolant channels corresponds to the rounded ratio of length and width of the supporting surface.

4. Coolable carrier plate according to claim 1, wherein each coolant channel is structured in a meandering manner.

5. Coolable carrier plate according to claim 1, wherein each network of coolant channels has an inlet collection channel through which the coolant is led from the coolant inlet into the coolant channels and an outlet collection channel through which the coolant is led from the coolant channels to the coolant outlet.

6. Coolable carrier plate according to claim 1, wherein the sealant is arranged in such a way that all coolant inlets and coolant outlets are separated from all fastening supports.

7. Coolable carrier plate according to claim 6, wherein all fastening supports are arranged on a vacuum side and all coolant inlets and coolant outlets are arranged on an atmosphere side of the carrier plate.

8. Coolable carrier plate according to claim 1, wherein each coolant inlet and each coolant outlet has an additional sealant.
